(19) United States
(12) Patent Application Publication
(10) Pub. No.: US 2006/0054915 A1
(43) Pub. Date: Mar. 16, 2006

(54) Led package

(75) Inventor: Hsiao Yi Chang, Taichung Hsien (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: SEN TECH Co., Ltd.

(21) Appl. No.: 11/223,290

(22) Filed: Sep. 9, 2005

(30) Foreign Application Priority Data
Sep. 10, 2004 (TW) 093214424

(51) Int. Cl. H01L 33/00

(52) U.S. Cl. 257/100

(57) ABSTRACT

A LED package includes a heat conductive base plate and a light emitting diode disposed thereon. A transparent encapsulating layer without luminescent powder seals the light emitting diode and a ventilation layer thereon is adapted to communicate with outside air. A luminescent plate is over the ventilation layer.

### BACKGROUND OF THE INVENTION

The invention relates to the field of a packaging design for light emitting diode (LED). More particularly, the invention relates to the field of a packaging design with heat dissipation for LED.

A number of LEDs that use semiconductor light emitting elements to produce light have been proposed. For example, a white LED can be produced by arranging a semiconductor light emitting element on a substrate and encapsulating it in a transparent resin containing fluorescent material.

However, if the distribution of the fluorescent material in the transparent resin is non-uniform, to remove the transparent resin will be difficult since it has been adhesively attached to the substrate. Furthermore, permeation by moisture and thermal expansion of air within the LED package may have adverse effects on the mechanical or light properties thereof.

### SUMMARY OF THE INVENTION

An exemplary embodiment of the invention provides a LED package including a heat conductive base plate and a light emitting diode disposed thereon. A transparent encapsulating layer without luminescent powder seals the light emitting diode and a ventilation layer thereon is adapted to communicate with outside air. A luminescent plate is over the ventilation layer.

Another exemplary embodiment of the invention provides a LED package including a heat conductive base plate and a light emitting diode thereon. A transparent encapsulating layer without luminescent powder seals the light emitting diode and a ventilation layer thereon is adapted to communicate with outside air. A lower opaque layer surrounds the heat conductive base plate and an upper opaque layer on the lower opaque layer surrounds the transparent encapsulating layer and the ventilation layer. A luminescent plate is over the ventilation layer. A narrower lower trench on the transparent encapsulating layer is surrounded by the upper opaque body for the ventilation layer formed therein. And a wider upper trench over the narrower lower trench is surrounded by the upper opaque body for the luminescent plate embedded therein to cover the ventilation layer.

### BRIEF DESCRIPTION OF THE DRAWINGS

The present invention will be described by way of exemplary embodiments, but not limitations, illustrated in the accompanying drawings in which like references denote similar elements, and in which:

FIG. 1 illustrates a sectional view of a LED package pertaining to an exemplary embodiment of the present invention;

FIG. 2 is a top view of the LED package of FIG. 1.

### DETAILED DESCRIPTION OF THE INVENTION

Various aspects of the system and method of the present invention will be described, and for purposes of explanation, specific configurations and details are set forth in order to provide a thorough understanding of the present invention. However, it will be apparent to one skilled in the art that the present invention may be practiced without these specific details. Furthermore, well known features have been omitted or simplified in order to prevent obscuring the present invention.

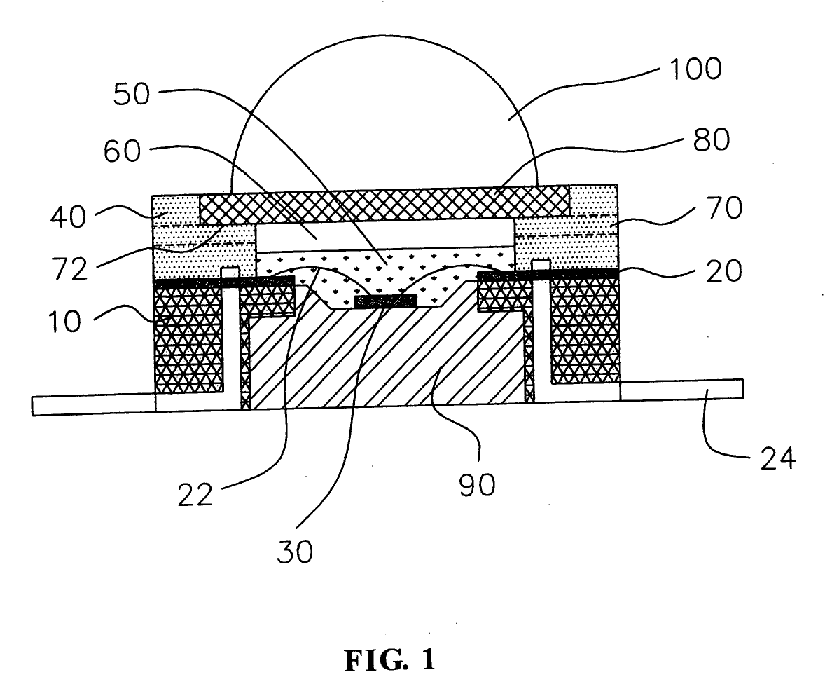

A sectional view of a LED package pertaining to an exemplary embodiment of the invention is shown in FIG. 1. The LED package comprises a heat conductive base plate 90 for good heat dissipation. Preferably, the heat conductive base plate 90 is a metal ring such as made of copper, but is not limited thereto.

A light emitting diode 30 disposed on the heat conductive base plate 90 in the present examples is a gallium nitride semiconductor element. A transparent encapsulating layer 50 therein may be formed over the outside of the LED 30 for sealing. Typically, the transparent encapsulating layer comprises resin, silicone resin, epoxy or glass for protecting the covered LED 30.

In conventional, a transparent resin containing phosphor powder may easily cause diminished transparence and impaired characteristics as a light emitting diode, since the distribution of the phosphor powder therein is usually non-uniform and the transparent resin is directly exposed on light output by the phosphor powder which is excited by the LED. On the other hand, the transparent resin containing phosphor powder is difficult to rework when it has been adhesively attached to the LED. Thus, by providing a specific embodiment of LED package using a transparent encapsulating layer without luminescent powder, the above undesirable effects could be avoided or minimized.

In an exemplary embodiment of the present invention, a provided ventilation layer 60 on the transparent encapsulating layer 50 is adapted to communicate with outside air. Preferably, the ventilation layer 60 is substantially made of air. Furthermore, the LED package may comprise a luminescent plate 80 for covering the ventilation layer 60.

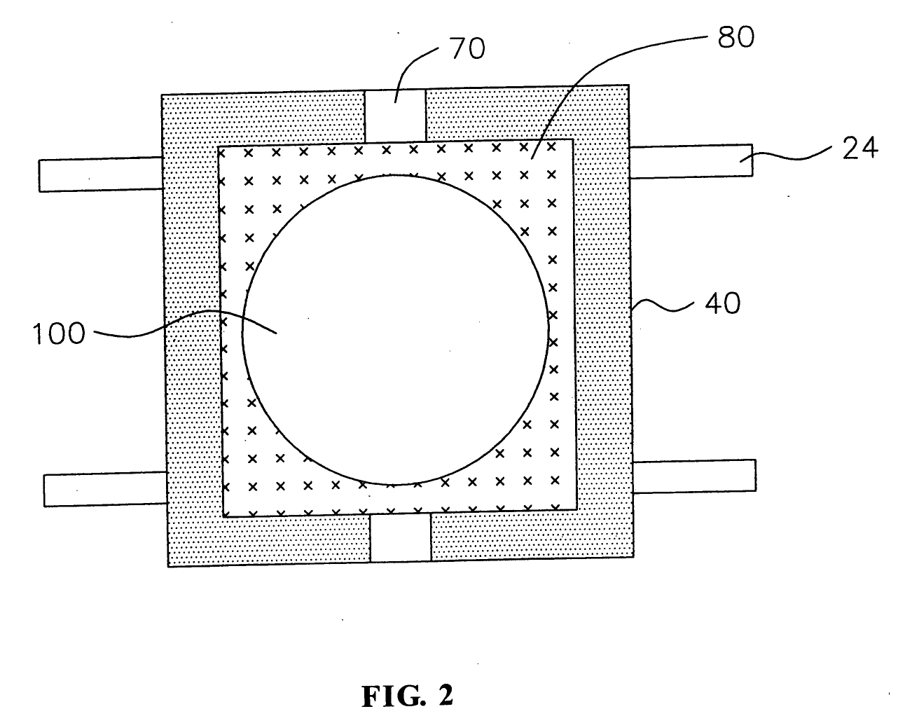

Referring to FIG. 1 and FIG. 2, the heat conductive base plate 90 in one example is surrounded by a lower opaque body 10. In addition, the transparent encapsulating layer 50 and the ventilation layer 60 are surrounded by an upper opaque body 40 formed on the lower opaque body 10. Typically, the lower opaque body 10 or the upper opaque body 40 may comprise ceramic material or nickel-plated brass.

The light emitted from the LED 30 could completely pass through the luminescent plate 80 since the lower opaque body 10 and the upper opaque body 40 prevent the light from traveling through the side surface of the LED package.

In one example, the upper opaque body 40 may further comprise at least a hole 70 for communication between the ventilation layer 60 and the outside air. Therefore, a heat dissipation path from the LED 30 along the encapsulating layer 50, the ventilation layer 60 and the hole 70 to the outside air could be formed. In addition, accumulated moisture or heat expanded air within the LED package could be vented out through the hole 70.

In another example, the LED package may further comprise a narrower lower trench on the transparent encapsulating layer 50 surrounded by the upper opaque body 40 for the ventilation layer 60 formed therein. And a wider upper trench over the narrower lower trench is surrounded by the upper opaque body for the luminescent plate 80 embedded therein to cover the ventilation layer 60. A renewal of the embedded luminescent plate 80 is thus easily performed when performance thereof is degraded, since the embedded luminescent plate 80 could be take apart easily.

The LED package further comprises contact electrodes 20 on the lower opaque body 10 for electrical connecting the light emitting diode 30. Furthermore, pins 24 passing through the lower opaque body 10 could electrical connect the contact electrodes 20.

In one example, the luminescent plate 80 may comprise a cured epoxy layer with a back side surface and a phosphor layer adhesively attached thereto. Typically, the phosphor layer is excited by light emitted from the light emitting diode 30. Preferably, the phosphor layer could be adhesively attached to the back side surface of the luminescent plate 80 by coating, screen printing, or dispensing a phosphor paste. Therefore, the distribution of the phosphor layer on the cured epoxy layer is more uniform. Even though the phosphor layer is non-uniform, the phosphor layer may be still easily removed from the cured epoxy layer.

Further referring to FIG. 1 and FIG. 2, the LED package preferably comprises a concave lens 100 to cover at least a portion of the luminescent plate 80 for collecting the light passing through the luminescent plate 80.

While the invention has been described by way of example and in terms of the preferred embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A LED package, comprising:
a heat conductive base plate;
a light emitting diode, disposed on the heat conductive base plate;
a transparent encapsulating layer without luminescent powder, sealing the light emitting diode;
a ventilation layer on the transparent encapsulating layer, adapted to communicate with outside air; and
a luminescent plate over the ventilation layer.

2. The LED package as recited in claim 1, wherein the heat conductive base plate comprises a metal ring.

3. The LED package as recited in claim 1, wherein the heat conductive base plate is surrounded by a lower opaque body.

4. The LED package as recited in claim 3, wherein the transparent encapsulating layer and the ventilation layer are surrounded by an upper opaque body formed on the lower opaque body.

5. The LED package as recited in claim 4, wherein the lower opaque body or the upper opaque body comprise ceramic material.

6. The LED package as recited in claim 4, wherein the lower opaque body or the upper opaque body comprise nickel-plated brass.

7. The LED package as recited in claim 4, wherein the upper opaque body comprises a hole for communication between the ventilation layer and the outside air.

8. The LED package as recited in claim 1, wherein the transparent encapsulating layer comprises resin, silicone resin, epoxy or glass.

9. The LED package as recited in claim 1, wherein the ventilation layer is substantially made of air.

10. The LED package as recited in claim 3, further comprising contact electrodes on the lower opaque body, wherein the contact electrodes electrical connect the light emitting diode.

11. The LED package as recited in claim 3, further comprising pins passing through the lower opaque body, wherein the pins electrical connect the contact electrodes.

12. The LED package as recited in claim 4, further comprising:
a narrower lower trench on the transparent encapsulating layer, surrounded by the upper opaque body for the ventilation layer formed therein; and
a wider upper trench over the narrower lower trench, surrounded by the upper opaque body for the luminescent plate embedded therein to cover the ventilation layer.

13. The LED package as recited in claim 1, wherein the luminescent plate comprises:
a cured epoxy layer with a back side surface; and
a phosphor layer, adhesively attached to the back side surface of the cured epoxy layer, being excited by light emitted from the light emitting diode.

14. The LED package as recited in claim 1, further comprising a concave lens covering at least a portion of the luminescent plate.

15. A LED package, comprising:
a heat conductive base plate;
a light emitting diode, disposed on the heat conductive base plate;
a transparent encapsulating layer without luminescent powder, sealing the light emitting diode;
a ventilation layer on the transparent encapsulating layer, adapted to communicate with outside air;
a lower opaque layer, surrounding the heat conductive base plate;
an upper opaque layer on the lower opaque layer, surrounding the transparent encapsulating layer and the ventilation layer;
a luminescent plate over the ventilation layer;
a narrower lower trench on the transparent encapsulating layer, surrounded by the upper opaque body for the ventilation layer formed therein; and
a wider upper trench over the narrower lower trench, surrounded by the upper opaque body for the luminescent plate embedded therein to cover the ventilation layer.

16. The LED package as recited in claim 15, wherein the upper opaque body comprises a hole for communication between the ventilation layer and the outside air.

17. The LED package as recited in claim 15, wherein the ventilation layer is substantially made of air.

18. The LED package as recited in claim 15, wherein the luminescent plate comprises:
a cured epoxy layer with a back side surface; and
a phosphor layer, adhesively attached to the back side surface of the cured epoxy layer, being excited by light emitted from the light emitting diode.

19. The LED package as recited in claim 15, further comprising a concave lens covering at least a portion of the luminescent plate.
